(19) United States
(12) Patent Application Publication
(10) Pub. No.: US 2012/0055535 A1
(43) Pub. Date: Mar. 8, 2012

(54) Photovoltaic Devices With Textured Glass Superstrate

(75) Inventors: Roman Gouk, San Jose, CA (US); Steven Verhaverbeke, San Francisco, CA (US); Kurtis Leschkies, Santa Clara, CA (US); Robert Visser, Menlo Park, CA (US)

(73) Assignee: Applied Materials, Inc., Santa Clara, CA (US)

(21) Appl. No.: 13/227,572

(22) Filed: Sep. 8, 2011

Related U.S. Application Data
(60) Provisional application No. 61/380,784, filed on Sep. 8, 2010.

(51) Int. Cl. H01L 31/042; H01L 31/18; H01L 31/0232

(52) U.S. Cl. 136/244; 136/256; 438/98; 257/E31.126

(57) ABSTRACT

Embodiments of the invention are directed to photovoltaic cells comprising a textured superstrate, a front contact layer, a photoabsorber layer and a back contact layer. The textured superstrate has a plurality of craters with an average opening angle, an average aspect ratio and an average depth. Methods of making such photovoltaic cells and photovoltaic modules are also described.

### CROSS-REFERENCE TO RELATED APPLICATIONS

This application claims the benefit under 35 U.S.C. §119(e) of U.S. Provisional Application No. 61/380,784, filed Sep. 8, 2010.

### BACKGROUND

Embodiments of the present invention generally relate to photovoltaic cells, photovoltaic modules and methods of making the same. Specific embodiments pertain to photovoltaic cells comprising a textured glass substrate upon which a thin film photovoltaic device is formed.

Light trapping is typically needed to enhance solar cell performance with incomplete light absorption with n the cell absorber cell. In thin film solar applications, primarily a-Si solar cells, light trapping is accomplished by texturing transparent conducting oxide films on glass substrates. Typical TCO films (such as zinc oxide and tin oxide) are less than about 1 μm thick and the maximum achievable roughness is less than about 0.5 μm with crevice features sized in the 1-2 μm range. This type of texture can be called micro-texture (within 1 μm range) can only effectively forward scatter light and trap light (or increase haze) in the 400-600 nm wavelength range, light scattering or haze in 600-1000 nm range is very low.

For tandem-junction type a-Si/μ-Si thin film solar cells, the top cell is optimized to absorb light in the 400-600 nm range and the bottom cell is optimized to absorb light in the 600-900 nm range, light trapping enhancement is needed in the IR light spectrum for the bottom cell.

In addition, micro-texturing the TCO layer creates sharp peaks which cause problems with the p-layer continuity and higher series resistance and lower fill factor. The lower fill factor (FF) reduces the conversion efficiency (CE) since it is directly proportional to the Fill Factor.

Therefore, there is a need in the art for photovoltaic devices and methods of manufacturing photovoltaic devices which have larger features sizes to achieve a broad-band haze and light trapping effect the cover the 400-1000 nm wavelength range.

### SUMMARY OF THE INVENTION

One or more embodiments of the invention are directed to photovoltaic cells. The photovoltaic cells comprise a superstrate, a front contact layer, a photoabsorber layer and a back contact layer. The superstrate has a textured top surface including a plurality of craters. The craters have an average opening angle, an average aspect ratio and an average depth with each crater having an individual opening angle. The aspect ratio is defined by the ratio of depth to width of each crater and depth. The front contact layer is on the top surface of the superstrate. The front contact layer conforms to the texture of the superstrate. The photoabsorber layer is on the front contact layer. The photoabsorber layer conforms to the texture of the superstrate. The back contact layer is on the photoabsorber layer. The back contact layer conforms to the texture of the superstrate. At least one of the average opening angle and the average aspect ratio is controlled to cause an increase of at least about 2% in surface area of the superstrate top surface.

Additional embodiments of the invention are directed to methods of making a photovoltaic cell. A front contact layer is deposited on a textured superstrate conforming to the superstrate texture. The textured superstrate has a plurality of craters with an average opening angle and an average aspect ratio defined by the ratio of depth to width of each crater. A photoabsorber layer is deposited on the front contact layer. The photoabsorber layer conforms to the textured superstrate and front contact layer. A back contact layer is deposited on the photoabsorber layer. The back contact layer conforms to the textured superstrate and the photoabsorber layer. One or more of the average opening angle and average aspect ratio is controlled to cause an increase of at least about 2% in surface area of the superstrate top surface.

In detailed embodiments, the average aspect ratio of the crater is greater than about 0.06. In specific embodiments, the average aspect ratio of the craters is in the range of about 0.12 to about 1. In detailed embodiments, the craters have an average depth greater than about 10 μm.

The average opening angle of some embodiments is less than about 170°. In detailed embodiments, the average opening angle is in the range of about 100° to 160°. In specific embodiments, the average opening angle is about 160°.

In some embodiments, one or more of the front contact layer and the back contact layer is a transparent conductive oxide. In detailed embodiments, the front contact layer is textured.

Further embodiments of the invention are directed to photovoltaic modules comprising a plurality of photovoltaic cells. In specific embodiments, the individual photovoltaic cells are connected in series.

In detailed embodiments, the textured superstrate is prepared by one or more of sand blasting, embossing and etching.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a cross-section of a photovoltaic cell according to one or more embodiments of the invention; and

FIG. 2 shows a cross-section of a superstrate in accordance with one or more embodiments of the invention.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

As used in this specification and the appended claims, the singular forms “a”, “an” and “the” include plural referents unless the context clearly indicates otherwise. For example, reference to a “cell” may also refer to more than one cells, and the like.

The terms “photovoltaic cell” and “solar cell” are used to describe an individual stack of layers suitable for converting light energy into electricity. The terms “photovoltaic module” and “solar module” are used to describe a device having a plurality of photovoltaic cells connected in series.

Photovoltaic devices may have a micro-textured front contact layer. As the front contact layer (often a transparent conductive oxide) is very thin, usually on the order of 1 μm in thickness. Therefore, the micro-texture formed on the front contact layer is also very thin (generally less than about 0.5 μm). A surface with a small texture, like these, can only trap light in the range of about 400 to about 600 nm. The micro-texture is limited to about half the thickness of the front contact layer. The sharp peaks created in the micro-texturing process can cause an increased risk of p-layer continuity issues, create higher series resistance and lower fill factor for the resultant device. Conversion efficiency (CE) is directly proportional to the fill factor (FF), therefore, a lower fill factor results in a reduction in the conversion efficiency (CE) of the device.

These micro-textured front contact layers are not effective to trap light with wavelengths in the range of about 600 nm to about 1000 nm. To trap light with these wavelengths, the size of the textured features must be larger (i.e., deeper) than can be formed in the thin front contact layer. The inventors have discovered that increasing the texturing feature size to greater than about 10 μm can result in broad band haze and light trapping effect that covers a wavelength range of about 400 nm to about 1000 nm. To achieve a texture size of greater than about 10 μm, also referred to as a macro-texture, the texture should be applied to the glass superstrate so that the front contact layer deposited on the glass superstrate conforms to the texture of the superstrate. As used in this specification and the appended claims, the term “superstrate” refers to a material that a photovoltaic cell comprising a plurality of individual layers is deposited on. The superstrate is a surface that will ultimately face the light source (e.g., the sun) after the resultant device has been put into use.

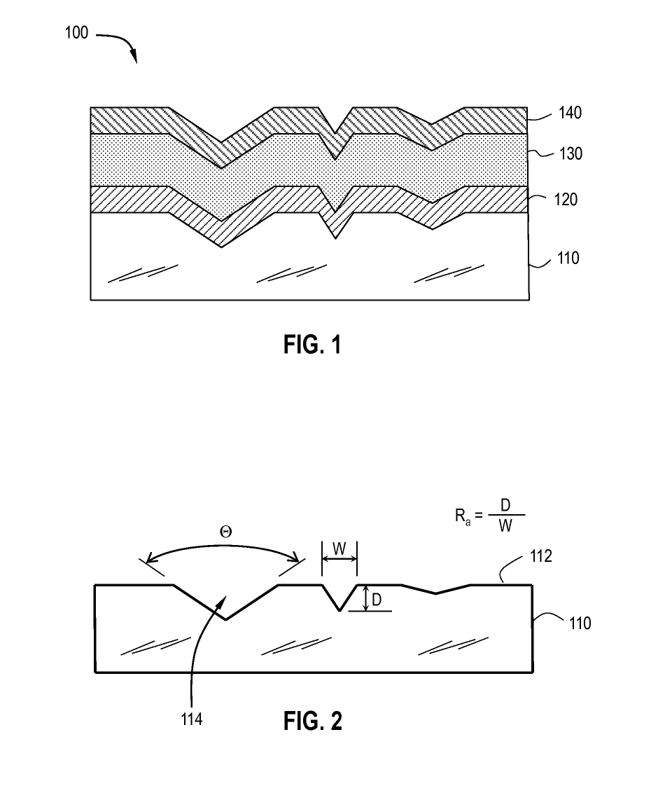

Accordingly, and with reference to FIGS. 1 and 2, one or more embodiments of the invention are directed to a photovoltaic cell 100 comprising a superstrate 110 having a textured top surface 112. The textured surface 112 includes a plurality of craters 114 with an average opening angle A_{Θ} and an average aspect ratio A_{Ra}. Each crater 114 has an individual opening angle Θ and aspect ratio Rₐ. The aspect ratio is defined as the ratio of depth D to width W of each crater 114. The opening angle Θ is measured as shown in FIG. 2.

The craters 114 creating the textured superstrate 110 can be prepared by any suitable technique known to those skilled in the art. Non-limiting examples of suitable techniques include sand blasting, embossing and etching. In specific embodiments, the superstrate 110 is textured by one or more of sand blasting, embossing and etching.

The average opening angle, the average aspect ratio and/or the average feature depth can be controlled, for example, to change the surface area of the top surface 112 of the superstrate 110. In specific embodiments, one or more of the average opening angle and average aspect ratio is controlled to cause an increase of at least about 2% in surface area of the superstrate 110 top surface 112. In some embodiments, one or more of the average opening angle and the average aspect ratio is controlled to cause an increase in the surface area of the superstrate 110 in the range of about 2% to about 97%. In various embodiments, one or more of the average opening angle and the average aspect ratio are controlled to cause an increase in the surface area of the superstrate 110 top surface 112 of at least about 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, 55%, 60%, 65%, 60%, 75%, 80%, 85%, 90%, 95% or 100%.

In addition to affecting the surface area of the superstrate 110, the inventors have discovered that the spectral haze is affected by the average opening angle of the craters 114. Table 1 shows the average spectral haze values for superstrates 110 with various average opening angles. It can be seen from Table 1 that as the average opening angle decreases, the average spectral haze increases. In some embodiments, the average opening angle is less than about 170°. In detailed embodiments the average opening angle is in the range of about 80° to about 170°. In various embodiments, the average opening angle is in the range of about 100° to about 160°, or in the range of about 120° to about 150°, or in the range of about 130° to about 140°. In specific embodiments, the average opening angle is about 160° or about 115°. In various embodiments, the average opening angle is less than about 170°, 160°, 155°, 150°, 145°, 140°, 135°, 130°, 125°, 120°, 115° or 110°.

TABLE 1

| Width | | | | |
|---|---|---|---|---|
| (μm) | Depth (μm) | Aspect Ratio | Opening Angle | Average Haze |
| 800 | 37 | 0.05 | 169° | 3% |
| 800 | 81 | 0.10 | 157° | 20% |
| 3000 | 1000 | 0.33 | 113° | 70% |

As can be seen from Table 1, the average aspect ratio, which is related to the opening angle, has an effect on the spectral haze. As the average aspect ratio increases, the average spectral haze value increases and the average opening angle decreases. The average aspect ratio of the craters 114 in the top surface 112 of the superstrate 110 can be controlled depending on the desired results. In detailed embodiments, the average aspect ratio of the craters 114 is greater than about 0.06. In specific embodiments, the average aspect ratio of the craters 114 is in the range of about 0.12 to about 1. In various embodiments, the average aspect ratio of the craters 114 is greater than about 0.12, or greater than about 0.15, or greater than about 0.2, or greater than about 0.3 or greater than about 0.4, or greater than about 0.5, or greater than about 0.6, or greater than about 0.7, or greater than about 0.8, or greater than about 0.9, or greater than about 1. In specific embodiments, the average aspect ratio of the craters 114 is about 0.10 or about 0.33.

The average depth of the craters 114 in the top surface 112 of the superstrate 110 has an effect on the light trapping ability of the device. In general, the average depth of the craters 114 is greater than the thickness of a front contact layer 120 applied to the superstrate 110. In detailed embodiments, the craters have an average depth greater than about 10 μm. In various embodiments, the average depth of the craters 114 is greater than about 5 μm, 7.5 μm, 12.5 μm, 15 μm, 20 μm, 25 μm, 30 μm, 35 μm, 40 μm, 45 μm, 50 μm, 55 μm, 60 μm, 65 μm, 70 μm, 75 μm, 80 μm, 85 μm, 90 μm, 95 μm, 100 μm, 150 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm or 1000 μm. In specific embodiments, the average depth of the craters 114 is about 80 μm or about 1000 μm.

Use of the textured superstrate 110 can help reduce lost efficiency from sunlight striking the superstrate 110 at an oblique angle. According to specific embodiments, the use of a textured superstrate 110 reduces the conversion efficiency dependence on the sun light incidence angle.

A front contact layer 120 is deposited on the top surface 112 of the superstrate 110. The macro-texture of the superstrate is transferred to the front contact layer 120 and the front contact layer 120 substantially conforms to the texture of the superstrate 110. As such, the average aspect ratio, depth and opening angle of the craters 114 are transferred through the front contact layer 120 to result in substantially similar features in the front contact layer 120. As used in this specification and the appended claims, the term “substantially similar” means that there is less than about a 10% difference. In more specific embodiments, there is less than about a 5% difference.

The front contact layer 120 can be made of any suitable material known to those skilled in the art. In some embodiments, the front contact layer is a transparent conductive oxide (TOO). Suitable TCO materials include, but are not limited to, zinc oxide, aluminum-doped zinc oxide (AZO), tin oxide, boron-doped zinc oxide, fluorine-doped tin oxide, indium tin oxide (ITO), indium molybdenum oxide (IMO), indium zinc oxide (IZO), tantalum oxide, nano-wire based transparent conductive electrodes (TCE) such as silver nano-wires and carbon nano-tubes and combinations thereof. Additionally, textured glass can be used to had haze factor to nano-wire based TCEs.

In some embodiments, the front contact layer is micro textured. Without being bound by any particular theory of operation, it is believed that a micro-textured front contact layer will enhance the light trapping in about the 400 nm to 700 nm light spectrum. Additionally, the macro-textured superstrate 110 is believed to increase the contact area of a photoabsorber layer 130 (or the first sub-layer of a photoabsorber layer 130) without creating sharp micro-peaks. This is believed to decrease the series resistance of the resulting device and increase the fill factor and conversion efficiency.

The front contact layer 120 can be deposited onto the superstrate 110 using any suitable method known to those skilled in the art. Suitable methods include, but are not limited to, physical vapor deposition (PVD), chemical vapor deposition (CVD) and atomic layer deposition (ALD).

A photoabsorber layer 130 is deposited on the front contact layer 120. The macro-texture of the superstrate 110 is transferred through the front contact layer 120 to the photoabsorber layer 130 so that the photoabsorber layer 130 conforms to the texture of the superstrate 110 and has substantially similar features to the front contact layer 120.

The photoabsorber layer 130 may be made of a combination of individual sub-layers. For example, a single-junction device may have a p-layer adjacent the front contact layer 120, with an intrinsic layer over the p-layer and an n-layer over the intrinsic layer. Individual sub-layers can be made of amorphous materials or crystalline materials, such as a-Si and μ-Si. Suitable materials for the photoabsorber layer 130 include any material capable of converting light energy to electrical current. Non-limiting examples of suitable materials include silicon, cadmium telluride, copper indium gallium selenide, and copper indium selenide. These materials can be doped with any suitable material as known to those skilled in the art. The photoabsorber layer 130, or individual sub-layers, can be deposited using any suitable method known to those skilled in the art including, but are not limited to, PVD, CVD, ALD and combinations thereof.

According to detailed embodiments, depositing a TCO layer as the front contact layer 120 on the macro-textured superstrate 110 increases the light trapping in the IR spectrum for a tandem junction Si thin film solar cell. In some embodiments, the deposition of a TCO layer as the front contact layer 120 and texturing the TCO layer gives bi-modal spectral haze for broad band light trapping (blue and IR wavelength regions). The use of textured glass superstrate can increase the fill factor of the resultant solar device.

A back contact layer 140 is deposited over the photoabsorber layer 130. The macro-texture of the superstrate 110 is transferred through the front contact layer 120 and the photoabsorber layer 130 to the back contact layer 140 so that the back contact layer 140 conforms to the texture of the superstrate 110 and has substantially similar features to the photoabsorber layer 130.

The back contact layer 140 can be made of any suitable material known to those skilled in the art. In some embodiments, the back contact layer 140 is a transparent conductive oxide (TOO). Suitable TCO materials for the back contact layer 140 include, but are not limited to, zinc oxide, aluminum-doped zinc oxide (AZO), tin oxide, boron-doped zinc oxide, fluorine-doped tin oxide, indium tin oxide (ITO), indium molybdenum oxide (IMO), indium zinc oxide (IZO) and tantalum oxide. The back contact layer 140 can be deposited using any suitable method known to those skilled in the art including, but are not limited to, PVD, CVD, ALD and combinations thereof.

In some embodiments, a reflective layer is deposited over the back contact layer 140. The reflective layer may include a material suitable to cause unabsorbed light passing through the photoabsorber layer 130 to be reflected. This provides a second chance for the photoabsorber layer 130 to absorb the light energy, increasing cell efficiency.

Additional embodiments of the invention are directed to photovoltaic modules comprising a plurality of photovoltaic cells 100 as previously described. The individual cells may be connected in series and can be made by any suitable method known to those skilled in the art. In specific embodiments, the series connections are created by a combination of individual scribe lines which are made in the layers. A first scribe line removes a portion of the front contact layer 120 before the photoabsorber layer 130 is deposited. A second scribe line removes a portion of the photoabsorber layer 130 before the back contact layer is deposited. The second scribe is parallel to the first scribe line. A third scribe line removes a portion of the back contact layer 140 and the photoabsorber layer 130. The third scribe is parallel to the second scribe and located on the opposite side of the second scribe. The combination of scribes results in a plurality of individual cells 100 where the back contact layer 140 of one cell is in electrical communication with the front contact layer 120 of the adjacent cell, creating a series connection between cells.

Reference throughout this specification to “one embodiment,” “certain embodiments,” “one or more embodiments,” “an embodiment,” “one aspect,” “certain aspects,” “one or more embodiments” and “an aspect” means that a particular feature, structure, material, or characteristic described in connection with the embodiment is included in at least one embodiment of the invention. Thus, the appearances of the phrases such as “in one or more embodiments,” “in certain embodiments,” “in one embodiment,” “in an embodiment,” “according to one or more aspects,” “in an aspect,” etc., in various places throughout this specification are not necessarily referring to the same embodiment or aspect of the invention. Furthermore, the particular features, structures, materials, or characteristics may be combined in any suitable manner in one or more embodiments or aspects. The order of description of the above method should not be considered limiting, and methods may use the described operations out of order or with omissions or additions.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

What is claimed is:

1. A photovoltaic cell comprising:
a superstrate having a textured top surface, the textured surface including a plurality of craters with an average opening angle, an average aspect ratio and an average depth with each crater having an individual opening angle, the aspect ratio defined by the ratio of depth to width of each crater and depth;
a front contact layer on the top surface of the superstrate, the front contact layer conforming to the texture of the superstrate;
a photoabsorber layer on the front contact layer, the photoabsorber layer conforming to the texture of the superstrate; and
a back contact layer on the photoabsorber layer, the back contact layer conforming to the texture of the superstrate, wherein at least one of the average opening angle and the average aspect ratio is controlled to cause an increase of at least about 2% in surface area of the superstrate top surface.

2. The photovoltaic cell of claim 1, wherein the average aspect ratio of the crater is greater than about 0.06.

3. The photovoltaic cell of claim 1, wherein the average aspect ratio of the craters is in the range of about 0.12 to about 1.

4. The photovoltaic cell of claim 1, wherein the average opening angle is less than about 170°.

5. The photovoltaic cell of claim 1, wherein the average opening angle is in the range of about 100° to 160°.

6. The photovoltaic cell of claim 1, wherein the average opening angle is about 160°.

7. The photovoltaic cell of claim 1, wherein one or more of the front contact layer and the back contact layer is a transparent conductive oxide.

8. The photovoltaic cell of claim 1, wherein the craters have an average depth greater than about 10 μm.

9. The photovoltaic cell of claim 1, wherein the front contact layer is textured.

10. The photovoltaic cell of claim 1, wherein the photovoltaic cell has a spectral haze greater than that of a similar photovoltaic cell without a textured superstrate.

11. A photovoltaic module comprising a plurality of photovoltaic cells according to claim 1.

12. The photovoltaic module of claim 11, wherein the individual photovoltaic cells are connected in series.

13. A photovoltaic cell comprising:
a superstrate having a textured top surface, the textured surface including a plurality of craters with an average opening angle less than about 170°, an average aspect ratio greater than about 0.06 and an average depth greater than about 10 μm, with each crater having an individual opening angle, the aspect ratio defined by the ratio of depth to width of each crater and depth;
a front contact layer on the top surface of the superstrate, the front contact layer conforming to the texture of the superstrate;
a photoabsorber layer on the front contact layer, the photoabsorber layer conforming to the texture of the superstrate; and
a back contact layer on the photoabsorber layer, the back contact layer conforming to the texture of the superstrate, wherein at least one of the average opening angle and the average aspect ratio is controlled to cause an increase of at least about 2% in surface area of the superstrate top surface.

14. A method of making a photovoltaic cell comprising:
depositing a front contact layer on a textured superstrate, the front contact layer conforming to the superstrate texture, the textured superstrate having a plurality of craters with an average opening angle and an average aspect ratio defined by the ratio of depth to width of each crater;
depositing a photoabsorber layer on the front contact layer, the photoabsorber layer conforming to the textured superstrate and front contact layer; and
depositing a back contact layer on the photoabsorber layer, the back contact layer conforming to the textured superstrate and the photoabsorber layer, wherein one or more of the average opening angle and average aspect ratio is controlled to cause an increase of at least about 2% in surface area of the superstrate top surface.

15. The method of claim 14 wherein the average aspect ratio of the craters is in the range of about 0.12 to about 1.

16. The method of claim 14, wherein the average opening angle is in the range of about 100° to 160°.

17. The method of claim 14, wherein one or more of the front contact layer and the back contact layer is a transparent conductive oxide.

18. The method of claim 14, wherein the craters have an average depth greater than about 10 μm.

19. The method of claim 14, wherein the textured superstrate is prepared by one or more of sand blasting, embossing and etching.

20. The method of claim 14, wherein the photovoltaic cell has a spectral haze greater than that of a similar photovoltaic cell without a textured superstrate.
